(19) United States
(12) Patent Application Publication
(10) Pub. No.: US 2024/0306452 A1
(43) Pub. Date: Sep. 12, 2024

(54) DISPLAY APPARATUS AND METHOD OF MANUFACTURING THE SAME

(71) Applicant: Samsung Display Co., Ltd., Yongin-si (KR)

(72) Inventors: Hyuneok Shin, Yongin-si (KR); Dokeun Song, Yongin-si (KR); Sukyoung Yang, Yongin-si (KR); Dongmin Lee, Yongin-si (KR)

(21) Appl. No.: 18/471,969

(22) Filed: Sep. 21, 2023

(30) Foreign Application Priority Data
Mar. 6, 2023 (KR) 10-2023-0029442

(51) Int. Cl. H10K 59/131; H10K 59/12

(52) U.S. Cl. CPC H10K 59/131; H10K 59/1201

(57) ABSTRACT

A display apparatus includes: a substrate comprising a display area and a peripheral area outside the display area; a display element on the display area; and a pad on the peripheral area and comprising a main metal layer and a protective metal layer on the main metal layer and comprising molybdenum (Mo), titanium (Ti), and nickel (Ni).

### CROSS-REFERENCE TO RELATED APPLICATION

The present application claims priority to and the benefit of Korean Patent Application No. 10-2023-0029442, filed on Mar. 6, 2023, in the Korean Intellectual Property Office, the entire disclosure of which is incorporated herein by reference.

### BACKGROUND

### 1. Field

Aspects of one or more embodiments relate to a display apparatus and a method of manufacturing the same.

### 2. Description of the Related Art

A display apparatus displays images by using a display element placed on a substrate including, for example, glass, etc. For example, regarding an organic light-emitting display apparatus, an organic light-emitting diode (OLED) may be used as a display element. Recently, in order to display images having an ultra-high resolution, display apparatuses in which display elements are arranged on a semiconductor substrate are being studied.

The display apparatuses display images by receiving information or data signals about the images, etc. To receive information about images, pads that are electrically connected to the display elements are placed on edges of the display apparatus. These pads are electrically connected to bumps of electronic chip packages or pads of printed circuit boards.

The above information disclosed in this Background section is only for enhancement of understanding of the background and therefore the information discussed in this Background section does not necessarily constitute prior art.

### SUMMARY

Aspects of one or more embodiments relate to a display apparatus and a method of manufacturing the same, and for example, to a display apparatus in which the probability of defects in a manufacturing process may be relatively reduced, and a method of manufacturing the display apparatus.

In the display apparatus of the related art, in a subsequent process after forming a pad, bonding to bumps of an electronic chip package etc. or the pads of the printed circuit board may not be easy as an upper surface of the pad is oxidized. One or more embodiments include a display apparatus in which the probability of defects in a manufacturing process may be reduced. However, these characteristics are merely examples and the scope of embodiments according to the present disclosure is not limited thereto.

Additional aspects will be set forth in part in the description which follows and, in part, will be more apparent from the description, or may be learned by practice of the presented embodiments of the disclosure.

According to one or more embodiments, a display apparatus may include a substrate including a display area and a peripheral area outside the display area, a display element on the display area, and a pad on the peripheral area and including a main metal layer and a protective metal layer on the main metal layer and including molybdenum (Mo), titanium (Ti), and nickel (Ni).

According to some embodiments, the protective metal layer may be in surface contact with the main metal layer.

According to some embodiments, the main metal layer may surround the protective metal layer in a plan view.

According to some embodiments, the pad may further include an auxiliary metal layer under the main metal layer.

According to some embodiments, the auxiliary metal layer may include titanium (Ti).

According to some embodiments, the auxiliary metal layer may further include Mo and Ni.

According to some embodiments, the main metal layer may be in surface contact with the auxiliary metal layer.

According to some embodiments, the auxiliary metal layer may surround the main metal layer in a plan view.

According to some embodiments, the main metal layer may include aluminum (Al).

According to some embodiments, the main metal layer may further include neodymium (Nd) or Ni.

According to some embodiments, the substrate may be a semiconductor substrate.

According to some embodiments, the display apparatus may further include an insulating layer located above the substrate and including a pad groove, wherein the pad is located in the pad groove of the insulating layer.

According to some embodiments, an upper surface of the insulating layer and an upper surface of the pad may form a flat surface.

According to one or more embodiments, a method of manufacturing a display apparatus may include forming an insulating layer on a substrate including a display area and a peripheral area surrounding the display area, forming a pad groove in a portion of the insulating layer on the peripheral area, forming an auxiliary metal layer forming layer on the insulating layer to cover the inner surface of the pad groove, forming a main metal layer forming layer on the auxiliary metal layer forming layer to cover the auxiliary metal layer forming layer in the pad groove, forming a protective metal layer forming layer including molybdenum (Mo), titanium (Ti), and nickel (Ni) on the main metal layer forming layer to cover the main metal layer forming layer in the pad groove, and forming a pad by removing each of a portion of the auxiliary metal layer forming layer, a portion of the main metal layer forming layer, and a portion of the protective metal layer forming layer, which are on the insulating layer outside the pad groove.

According to some embodiments, the forming of the pad by removing each of the portion of the auxiliary metal layer forming layer, the portion of the main metal layer forming layer, and the portion of the protective metal layer forming layer may include proceeding chemical mechanical polishing (CMP) to expose the upper surface of the insulating layer and for the upper surface of the insulating layer to form a flat surface with the upper surface of the pad.

According to some embodiments, the auxiliary metal layer forming layer may include Ti.

According to some embodiments, the auxiliary metal layer forming layer may further include Mo and Ni.

According to some embodiments, the main metal layer forming layer may include Al.

According to some embodiments, the main metal layer forming layer may further include Nd or Ni.

According to some embodiments, the substrate may be a semiconductor substrate.

Other aspects, features, and characteristics other than those described above will become more apparent from the following detailed description, the appended claims, and the accompanying drawings.

### BRIEF DESCRIPTION OF THE DRAWINGS

The above and other aspects, features, and characteristics of certain embodiments of the disclosure will be more apparent from the following description taken in conjunction with the accompanying drawings, in which:

FIG. 1 is a schematic plan view of a display panel of a display apparatus according to some embodiments;

FIG. 2 is an equivalent circuit diagram of a pixel circuit that is included in the display apparatus according to some embodiments;

FIG. 3 is a cross-sectional view of the display panel of FIG. 1, taken along the line I-I′ and line II-II′;

FIG. 4 is a schematic plan view of an enlarged portion A of the display panel of FIG. 1;

FIG. 5 is a cross-sectional view of the display panel of FIG. 4, taken along the line III-III′; and

FIGS. 6 to 11 are cross-sectional views schematically illustrating a portion of a process of manufacturing the display panel of FIG. 3.

### DETAILED DESCRIPTION

Reference will now be made in more detail to aspects of some embodiments, which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b or c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in more detail. The effects and features of the disclosure and the accomplishing methods thereof will become apparent from the embodiments described below in more detail with reference to the accompanying drawings. However, the disclosure is not limited to the embodiments described below and may be embodied in various modes.

In the specification, the terms “first” and “second” are not used in a limited sense and are used to distinguish one component from another component.

As used herein, the singular expressions “a,” “an,” and “the” are intended to include the plural forms as well, unless the context clearly indicates otherwise.

It will be further understood that the terms “comprises” or “comprising” used herein specify the presence of stated features or components, but do not preclude the presence or addition of one or more other features or components.

An expression used herein such as “A and/or B” indicates A, B, or A and B. “At least one of A and B” is used to select only A, select only B, or select both A and B.

It will be understood that when a component, such as a layer, a film, a region, or a plate, is referred to as being “on” another component, the component may be directly on the other component or intervening components may be present therebetween.

It will be understood that when a layer, region, or component is referred to as being “connected to” another layer, region, or component, the layer, region, or component may be directly connected to the another layer, region, or component, and/or indirectly connected to the another layer, region, or component as intervening layer, region, or component is present. For example, it will be understood that when a layer, region, or component is referred to as being “electrically connected to” another layer, region, or component, the layer, region, or component may be directly electrically connected to the another layer, region, and/or component, or indirectly electrically connected to the another layer, region, or component as intervening layer, region, or component is present.

In the present specification, the x-axis, y-axis, and z-axis are not limited to three axes in an orthogonal coordinate system, and may be interpreted in a broad sense including these axes. For example, the x-axis, y-axis, and z-axis may refer to those orthogonal to each other, or may refer to those in different directions that are not orthogonal to each other.

When a specific example may be implemented differently, a specific process order may be performed differently from the described order. For example, two consecutively described processes may be performed substantially at the same time or may be performed in an order opposite to the described order.

One or more embodiments will now be described more fully with reference to the accompanying drawings, and like reference numerals in the drawings denote like elements, and thus their description will be omitted. Also, sizes of elements in the drawings may be exaggerated or reduced for convenience of explanation. In other words, because the sizes and thicknesses of elements in the drawings are arbitrarily illustrated for convenience of description, the disclosure is not limited thereto.

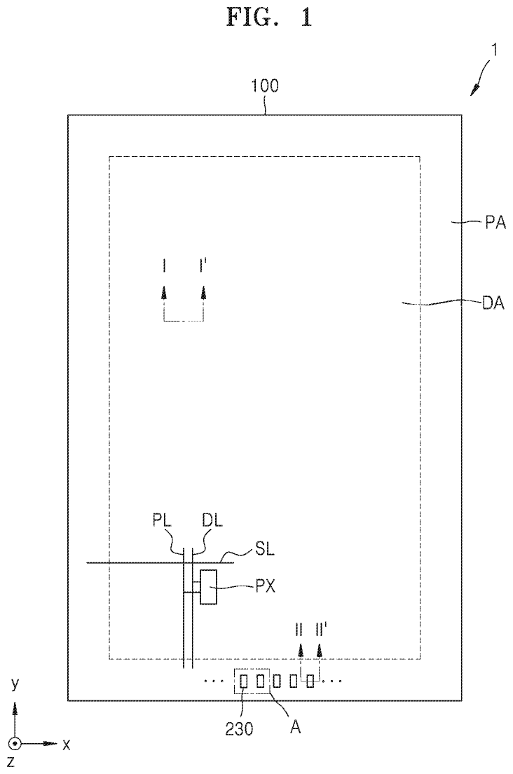

FIG. 1 is a schematic plan view of a display panel 1 of a display apparatus according to some embodiments.

As shown in FIG. 1, the display apparatus according to some embodiments includes a display panel 1. The display apparatus may be any display apparatus that includes the display panel 1. For example, the display apparatus may include various apparatuses, such as smartphones, tablet personal computers (PCs), laptop PCs, televisions, or advertisement boards.

The display panel 1 may include a display area DA and a peripheral area PA outside (e.g., in a periphery or outside a footprint of) the display area DA. FIG. 1 illustrates that the display area DA has a rectangular shape. However, embodiments according to the present disclosure are not limited thereto. The display area DA may have various shapes, such as a circular shape, an oval shape, a polygonal shape, a shape of a specific figure, and the like.

The display area DA is a portion for displaying images, in which a plurality of pixels PX may be arranged. Each of the pixels PX may include a display element, such as an organic light-emitting diode. For example, each pixel PX may emit red, green, or blue light. Each pixel PX may be connected to a pixel circuit including a thin film transistor (TFT), a storage capacitor, and the like. The pixel circuit may be connected to a scan line SL configured to transmit a scan signal, a data line DL crossing (and electrically insulated from) the scan line SL and configured to transmit a data signal, a driving voltage line PL configured to supply a driving voltage, and the like. The scan line SL may extend in an x direction, and the data line DL and the driving voltage line PL may each extend in a y direction. Although FIG. 1 illustrates, for convenience of illustration, a single pixel PX, a single data line DL, a single scan line SL, and a single driving voltage line PL, a person having ordinary skill in the art would recognize that the display panel 1 may include a plurality of the above elements, and the number may vary according to the design and size of the display panel 1.

The pixels PX may emit light having a brightness corresponding to an electronic signal (e.g., a data signal) from the pixel circuit electrically connected thereto. The display area DA may display a certain image through light emitted collectively from each pixel PX. For reference, each pixel PX may be defined as a light-emitting area that emits light of any one color of red, green, and blue, as described above.

The peripheral area PA is an area in which the pixels PX are not arranged and may be an area in which no images are displayed. A power supply line or the like for driving the pixels PX may be located in the peripheral area PA. In addition, a pad 230 that is electrically and mechanically connected to a printed circuit board including a driving circuit unit or an electronic chip package including an integrated circuit (IC) chip may be arranged in the peripheral area PA.

For reference, as the display panel 1 includes a substrate 100, it may be said that the substrate 100 includes the display area DA and the peripheral area PA. The substrate 100 is described below in more detail.

Hereinafter, an organic light-emitting display apparatus will be described as an example of the display apparatus according to some embodiments. However, the display apparatus according to some embodiments of the present disclosure is not limited thereto. For example, the display apparatus according to some embodiments of the present disclosure may include an inorganic light-emitting display apparatus (or an inorganic electroluminescent (EL) display apparatus) or a quantum dot light-emitting display. For example, an emission layer of a display element included in the display apparatus may include an organic material or an inorganic material. The display apparatus may include an emission layer and quantum dots located on the path of light emitted by the emission layer.

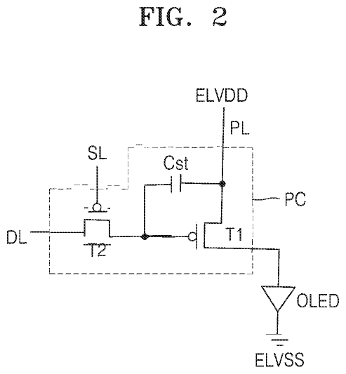

FIG. 2 is an equivalent circuit diagram of a pixel circuit PC that is included in the display apparatus according to some embodiments. The pixel circuit PC may be electrically connected to a display element, and one display element may correspond to one pixel PX. For example, the display element may be an organic light-emitting diode OLED.

The pixel circuit PC may include a first transistor T1, a second transistor T2, and a storage capacitor Cst. The second transistor T2 is a switching transistor and is connected to the scan line SL and the data line DL, and may be configured to transfer, to the first thin-film transistor T1, a data signal turned on by a switching signal input form the scan line SL and input from the data line DL. An end of the storage capacitor Cst is electrically connected to the second transistor T2 and the other end of the storage capacitor Cst is electrically connected to the driving voltage line PL, and the storage capacitor Cst may store a voltage corresponding to a difference between a voltage received from the second transistor T2 and a driving power supply voltage ELVDD supplied to the driving voltage line PL.

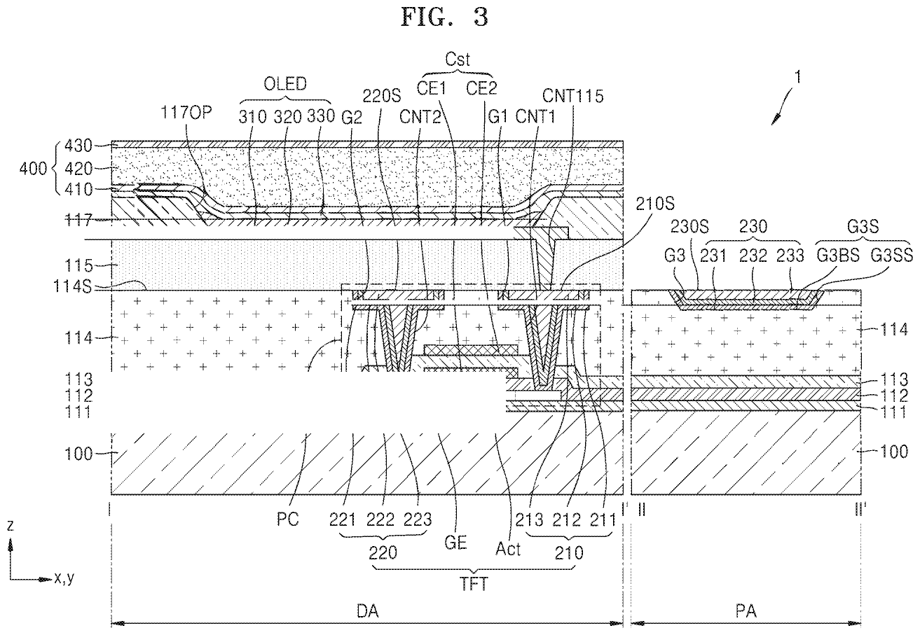

The first transistor T1 may be a driving transistor, may be connected to the driving voltage line PL and the storage capacitor Cst, and may be configured to control a size of a driving current flowing from the driving voltage line PL through the organic light-emitting diode OLED, according to a value of the voltage stored in the storage capacitor Cst. The organic light-emitting diode OLED may emit light with a certain brightness according to the driving current. A counter electrode 330 (refer to FIG. 3) of the organic light-emitting diode OLED may receive an electrode power supply voltage ELVSS.

FIG. 2 illustrates that the pixel circuit PC includes two transistors and one storage capacitor. However, embodiments according to the present disclosure are not limited thereto. For example, the number of transistors or the number of storage capacitors may be variously modified according to the design of the pixel circuit PC. For example, some embodiments may include additional components or fewer components without departing from the spirit and scope of embodiments according to the present disclosure.

FIG. 3 is a cross-sectional view of the display panel 1 of FIG. 1, taken along the line I-I′ and the line II-II′.

As shown in FIG. 3, the display panel 1 included in the display apparatus according to some embodiments may include the substrate 100. As described above, the substrate 100 may include the display area DA and the peripheral area PA outside the display area DA.

The substrate 100 may include a semiconductor material such as a Group IV semiconductor, a Group III-V compound semiconductor, or a Group II-VI compound semiconductor. That is, the substrate 100 may be a semiconductor substrate including a semiconductor material. For example, the substrate 100 may include silicon Si. That is, the substrate 100 may include a silicone substrate (a silicon semiconductor substrate). For example, the substrate 100 may be a silicon wafer. The silicon wafer may be a monocrystalline silicon wafer, a polycrystalline silicon wafer, or an amorphous silicon wafer.

As such, the organic light-emitting diode display apparatus using a semiconductor substrate as the substrate 100 may be referred to as an organic light-emitting diode on silicon (OLEDoS). Because the OLEDoS uses a semiconductor substrate as the substrate 100, the manufacturing process of a thin-film transistor, which is commonly used in the semiconductor technology field, may be applied to the manufacturing process of the display apparatus. Thus, the formation of the ultra-small pixel and the control of such a pixel may be possible, and the OLEDoS may display images having an ultra-high resolution.

In some cases, the type of substrate 100 may not be limited to a semiconductor substrate. For example, the substrate 100 may include glass, a metal, or a polymer resin. Also, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have various modifications, for example, a multiplayer structure of two layers including polymer resin as above and a barrier layer arranged between the two layers and including an inorganic material, such as a silicon oxide (SiO_{X}), a silicon nitride (SiN_{X}), a silicon oxynitride (SiO_{X}N_{Y}), or the like. Hereinafter, the substrate 100 will be described in more detail based on a case in which the substrate 100 is a silicon substrate, but embodiments according to the present disclosure are not limited thereto.

The display element and the pixel circuit PC that is electrically connected to the display element may be located on the substrate 100. The pixel circuit PC may include a plurality of thin-film transistors TFT and the storage capacitor Cst. FIG. 3 illustrates that, as a display element, the organic light-emitting diode OLED is located on the substrate 100. The organic light-emitting diode OLED being electrically connected to the pixel circuit PC may be understood as pixel electrode 310 included in the organic light-emitting diode OLED being electrically connected to the thin-film transistor TFT of the pixel circuit PC. For convenience of illustration, the thin-film transistor TFT of FIG. 3 may correspond to the first transistor T1 (refer to FIG. 2) described above.

A buffer layer 111 including inorganic materials such as SiO_{X}, SiN_{X}, and/or silicon oxynitride SiO_{X}N_{Y} may be arranged between the thin-film transistor TFT and the substrate 100. For example, the buffer layer 111 may be formed on a front surface of the substrate 100. In this case, the buffer layer 111 may also be located on the peripheral area PA. That is, the buffer layer 111 may also be located below the pad 230. The buffer layer 111 may planarize a top surface of the substrate 100 or may prevent, reduce, or minimize impurities from the substrate 100 or the like from penetrating into a semiconductor layer Act of the thin-film transistor TFT.

The thin-film transistor TFT may include a semiconductor layer Act including amorphous silicon, polycrystalline silicon, an organic semiconductor material, or an oxide semiconductor material, a gate electrode GE, a first connection electrode 210, and a second connection electrode 220. For example, the first connection electrode 210 may be a source electrode, and the second connection electrode 220 may be a drain electrode. Alternatively, the first connection electrode 210 may be a drain electrode and the second connection electrode 220 may be a source electrode, according to the polarity of the thin-film transistor TFT. The gate electrode GE may include various conductive materials and have various layered structures, including a molybdenum (Mo) layer and an aluminum (Al) layer. In some embodiments, the gate electrode GE may include a titanium nitride (TiNₓ) layer, an Al layer, and/or a titanium (Ti) layer. The first connection electrode 210 and the second connection electrode 220 may also include various conductive materials and have various layer structures.

To ensure insulation between the semiconductor layer Act and the gate electrode GE, a first insulating layer including inorganic materials such as SiO_{X}, SiN_{X}, and/or SiO_{X}N_{Y} may be arranged between the semiconductor layer Act and the gate electrode GE. For example, the first insulating layer 112 may be formed on the entire surface of the substrate 100 to cover the semiconductor layer Act. In this case, the first insulating layer 112 may also be located on the buffer layer 111 of the peripheral area PA. That is, the first insulating layer 112 may also be located below the pad 230.

The second insulating layer 113 including inorganic materials such as SiO_{X}, silicon nitride SiN_{X}, and/or SiO_{X}N_{Y} may be arranged on the gate electrode GE. For example, the second insulating layer 113 may be formed on the entire surface of the substrate 100 to cover the gate electrode GE. In this case, the second insulating layer 113 may also be located on the first insulating layer 112 of the peripheral area PA. That is, the second insulating layer 113 may also be located below the pad 230. The second insulating layer 113 may include a single layer or multiple layers including the materials described above.

The storage capacitor Cst may include a first capacitor electrode CE1 and a second capacitor electrode CE2 overlapping each other with the second insulating layer 113 therebetween. In this regard, FIG. 3 illustrates that the gate electrode GE of the thin-film transistor TFT is the first capacitor electrode CE1 of the storage capacitor Cst, but the disclosure is not limited thereto. For example, the storage capacitor Cst may not overlap the thin-film transistor TFT. The second capacitor electrode CE2 of the storage capacitor Cst may include a conductive material including Mo, Al, Cu, Ti, etc. and may include layers or a single layer including the materials described above.

A third insulating layer 114 including inorganic materials such as SiO_{X}, SiN_{X}, and/or SiO_{X}N_{Y} may be arranged on the second capacitor electrode CE2 of the storage capacitor Cst. For example, the third insulating layer 114 may be formed on the entire surface of the substrate 100 to cover the second capacitor electrode CE2. In this case, the third insulating layer 114 may also be located on the peripheral area PA. The third insulating layer 114 may include a single layer or multiple layers including the materials described above.

The insulating layers including inorganic materials may be formed by chemical vapor deposition (CVD) or atomic layer deposition (ALD). This is also true for embodiments to be described in more detail later and modifications thereof.

The third insulating layer 114 may include a first groove G1, a second groove G2, and a pad groove G3. A groove may not penetrate the third insulating layer 114. That is, each of the first groove G1, the second groove G2, and the third groove G3 may be formed by removing only a portion of the third insulating layer 114 from the upper surface thereof in the thickness direction. For example, the first groove G1 and the second groove G2 may be provided in portions of the third insulating layer 114 in the display area DA, and the pad groove G3 may be provided in a portion of the third insulating layer 114 of the peripheral area PA.

The first connection electrode 210 may be arranged in the first groove G1, and the second connection electrode 220 may be arranged in the second groove G2. Each of the first connection electrode 210 and the second connection electrode 220 may be connected to the source region or the drain region of the semiconductor layer Act through a contact hole formed in the first insulating layer 112, the second insulating layer 113, and the third insulating layer 114. For example, the first connection electrode 210 may be connected to the source region of the semiconductor layer Act through a first contact hole CNT1, and the second connection electrode 220 may be connected to the drain region of the semiconductor layer Act through a second contact hole CNT2.

The first connection electrode 210 and the second connection electrode 220 are arranged in the first groove G1 and the second groove G2, respectively, and an upper surface 210S of the first connection electrode 210 and an upper surface 220S of the second connection electrode 220 may form a flat surface with an upper surface 114S of the third insulating layer 114. That is, the upper surface 210S of the first connection electrode 210 and the upper surface 220S of the second connection electrode 220 may form a flat surface with the upper surface 114S of the third insulating layer 114 without forming a step difference with the upper surface 114S of the third insulating layer 114.

When the first connection electrode 210 and the second connection electrode 220 are placed on the upper surface 114S of the third insulating layer 114, the upper surface 210S of the first connection electrode 210 and the upper surface 220S of the second connection electrode 220 may form a step difference with the upper surface 114S of the third insulating layer 114. However, according to some embodiments, as described in more detail later, layers for forming the first connection electrode 210 and the second connection electrode 220 are formed in the first groove G1 and the second groove G2, and, through a polishing process, the upper surface 210S of the first connection electrode 210, the upper surface 220S of the second connection electrode 220, and the upper surface 114S of the third insulating layer 114 are planarized. That is, the upper surface 210S of the first connection electrode 210 and the upper surface 220S of the second connection electrode 220 may form a flat surface with the upper surface 114S of the third insulating layer 114 without forming a step difference with the upper surface 114S of the third insulating layer 114.

However, embodiments according to the present disclosure are not limited thereto. For example, the thin-film transistor TFT may include either the first connection electrode 210 or the second connection electrode 220, or may not include both the first connection electrode 210 and the second connection electrode 220. For example, the thin-film transistor TFT may not include the second connection electrode 220, another thin-film transistor TFT connected to the thin-film transistor TFT may not include first connection electrode 210, and the semiconductor layers Act of the two transistors TFT may be connected to each other. Such a connection structure may have the same effect as when a transistor includes the first connection electrode 210 and the other transistor includes the second connection electrode 220, and the first connection electrode 210 of the transistor is connected to the second connection electrode 220 of the other transistor.

The first connection electrode 210 and the second connection electrode 220 of the thin-film transistor TFT may be formed together in a process for forming the pad 230. Therefore, the first connection electrode 210 and the second connection electrode 220 may include multiple layers like the pad 230. The multi-layer structure will be described below in more detail. According to some embodiments, at least one of the first connection electrode 210 and the second connection electrode 220 may be electrically connected to a signal line arranged in the display area DA.

An organic insulating layer 115 may be located on the first connection electrode 210, the second connection electrode 220, and the third insulating layer 114. For example, the organic insulating layer 115 may be formed on the display area DA of the substrate 100 to cover the first connection electrode 210, the second connection electrode 220, and the third insulating layer 114. As a display element, the organic light-emitting diode OLED may be located on the organic insulating layer 115.

The organic insulating layer 115 may have a flat upper surface such that the pixel electrode 310 of the organic light-emitting diode OLED may be flat. The organic insulating layer 115 may include an organic insulating material. For example, the organic insulating layer 115 may include general purpose polymers such as benzocyclobutene (BCB), polyimide, hexamethyldisiloxane (HMDSO), polymethylmethacrylate (PMMA), or polystyrene (PS), polymer derivatives having a phenolic group, acrylic polymers, imide-based polymers, arylether-based polymers, amide-based polymers, fluorine-based polymers, p-xylene-based polymers, vinyl alcohol-based polymers, a blend thereof, and the like. The organic insulating layer 115 may include a single layer or multiple layers including the materials described above.

In FIG. 3, the organic insulating layer 115 is located only above the display area DA of the substrate 100, but embodiments according to the present disclosure are not limited thereto. For example, because the organic insulating layer 115 is formed on the entire surface of the substrate 100, the organic insulating layer 115 may be located above the peripheral area PA of the substrate 100. In this case, the organic insulating layer 115 may have an opening that exposes a central portion of the pad 230.

As described above, the organic light-emitting diode OLED, as a display element, may be located on the organic insulating layer 115. The organic light-emitting diode OLED may include the pixel electrode 310, the counter electrode 330, and an emission layer 320 between the pixel electrode 310 and the counter electrode 330. As shown in FIG. 3, the pixel electrode 310 may contact either the first connection electrode 210 or the second connection electrode 220 via a contact hole CNT115 formed in the organic insulating layer 115 and be electrically connected to the thin-film transistor. The pixel electrode 310 may include a light-transmitting conductive layer and a reflective layer, in which the light-transmitting conductive layer includes a light-transmitting conductive oxide, such as indium tin oxide (ITO), indium oxide (In₂O₃), and indium zinc oxide (IZO), and the reflective layer includes metal such as Al or silver (Ag). For example, the pixel electrode 310 may have a three-layered structure of ITO/Ag/ITO.

The emission layer 320 of the organic light-emitting diode OLED may include a low molecular weight organic material or a high molecular weight organic material. For example, the emission layer 320 may include polymer materials such as polyphenylene vinylene (PPV) and polyfluorene. The emission layer 320 may be formed by using screen printing, inkjet printing, laser-induced thermal imaging (LITI), or the like. However, one or more embodiments are not limited thereto.

According to some embodiments, a functional layer may be located below and above the emission layer 320. The functional layer may include a hole injection layer (HIL), a hole transport layer (HTL), an electron transport layer (ETL), and/or an electronic injection layer (EIL). The functional layer may be integrally formed across the plurality of pixel electrodes 310, or may be patterned to correspond to each of the plurality of pixel electrodes 310.

The counter electrode 330 may be arranged above the display area DA to cover the display area DA as shown in FIG. 3. That is, the counter electrode 330 may be integrally formed in a plurality of organic light-emitting diodes OLED to correspond to a plurality of pixel electrodes 310. The counter electrode 330 may include a light-transmitting conductive layer formed of ITO, In₂O₃, or IZO, and may include a semi-transmissive film including a metal such as Al or Ag. For example, the counter electrode 330 may be a semi-transmissive film including Mg or Ag.

A pixel defining layer 117 may be located on the organic insulating layer 115.

The pixel defining layer 117 may define a pixel by including an opening 117OP corresponding to each pixel, that is, an opening 117OP that exposes at least a central portion of the pixel electrode 310. In addition, in the case as shown in FIG. 3, the pixel defining layer 117 may prevent or reduce instances of an arc occurring on the edges of the pixel electrode 310 by increasing distances between edges of the pixel electrode 310 and the counter electrode 330. The pixel defining layer 117 may include an organic material such as polyimide or hexamethyldisiloxane (HMDSO).

As the organic light-emitting diode OLED is easily damaged by external moisture, oxygen, and the like, an encapsulation layer 400 is further provided to cover and protect the organic light-emitting diode OLED. The encapsulation layer 400 may cover the display area DA and may extend to the outside of the display area DA. The encapsulation layer 400 may include a first inorganic encapsulation layer 410, an organic encapsulation layer 420, and a second inorganic encapsulation layer 430 as shown in FIG. 3.

The first inorganic encapsulation layer 410 may cover the counter electrode 330, and may include SiO_{X}, SiN_{X}, and/or SiO_{X}N_{Y}. When necessary, other layers such as a capping layer may be arranged between the first inorganic encapsulation layer 410 and the counter electrode 330. Because the first inorganic encapsulation layer 410 is formed along a lower structure, an upper surface of the first inorganic encapsulation layer 410 is not flat as shown in FIG. 3. The organic encapsulation layer 420 covers the first inorganic encapsulation layer 410. In contrast with the first inorganic encapsulation layer 410, the organic encapsulation layer 420 may have an approximately flat upper surface. For example, a portion of the organic encapsulation layer 420 corresponding to the display area DA may have a substantially flat upper surface.

The organic encapsulation layer 420 may include at least one material selected from the group consisting of polyethylene terephthalate, polyethylene naphthalate, polycarbonate, polyimide, polyethylene sulfonate, polyoxymethylene, polyarylate, and hexamethyldisiloxane. The second inorganic encapsulation layer 430 may cover the organic encapsulation layer 420, and may include SiO_{X}, SiN_{X}, and/or SiO_{X}N_{Y}. An edge of the second inorganic encapsulation layer 430 located outside the display area DA may in contact with the first inorganic encapsulation layer 410 to prevent or reduce instances of the organic encapsulation layer 420 being exposed to the outside.

As such, because the encapsulation layer 400 includes the first inorganic encapsulation layer 410, the organic encapsulation layer 420, and the second inorganic encapsulation layer 430, even when the encapsulation layer 400 cracks due to such a multi-layered structure, the crack may not be connected between the first inorganic encapsulation layer 410 and the organic encapsulation layer 420 or between the organic encapsulation layer 420 and the second inorganic encapsulation layer 430. Accordingly, the formation of a path through which external moisture or oxygen penetrates into the display area DA may be prevented, reduced, or minimized.

The pad 230 may be located on the peripheral area PA. As described above, the third insulating layer 114 may include the first groove G1, the second groove G2, and the pad groove G3. For example, the pad groove G3 may be provided in a portion of the third insulating layer 114 above the peripheral area PA. The pad 230 may be arranged in the pad groove G3. As the pad 230 is arranged in the pad groove G3, the upper surface 230S of the pad 230 may form a flat surface with the upper surface 114S of the third insulating layer 114. That is, the upper surface 230S of the pad 230 and the upper surface 114S of the third insulating layer 114 may form a flat surface without forming a step difference therebetween.

When the pad 230 is located on the upper surface 114S of the third insulating layer 114, a step difference between the upper surface 230S of the pad 230 and the upper surface 114S of the third insulating layer 114 may be formed by the thickness of the third insulating layer 114. However, according to some embodiments, as will be described later, layers for forming the pad 230 are formed in the pad groove G3, and, through a polishing process, the upper surface 230S of the pad and the upper surface 114S of the third insulating layer are planarized. That is, the upper surface 230S of the pad 230 and the upper surface 114S of the third insulating layer 114 may form a flat surface without forming a step difference therebetween.

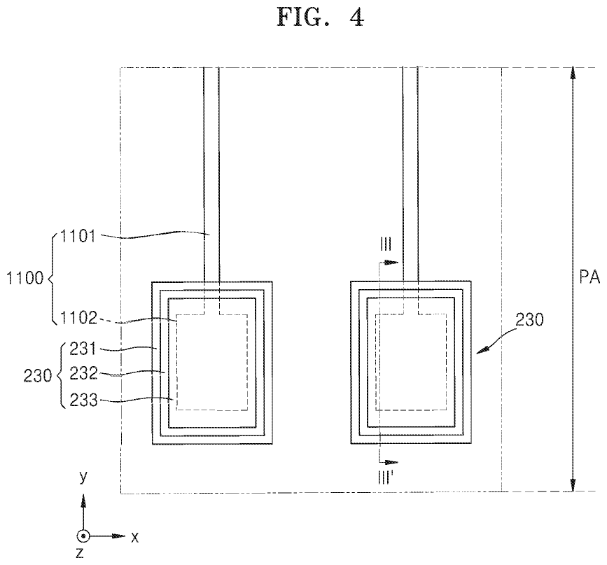

The pad 230 may be electrically connected to the signal line arranged in the display area DA. According to some embodiments, as shown in FIG. 4, which is a plan view of portion A of the display panel 1 of FIG. 1, the pad 230 may overlap a portion of a connection line. For example, the connection lines 1100 may be arranged in the peripheral area PA. The connection lines 1100 may electrically connect the signal lines arranged in the display area DA, such as data lines, to the pads 230. Each of the connection lines 1100 may include a first portion 1101 extending in one direction and a second portion 1102 arranged at an end of the first portion 1101 to electrically connect the signal line to the pad 230.

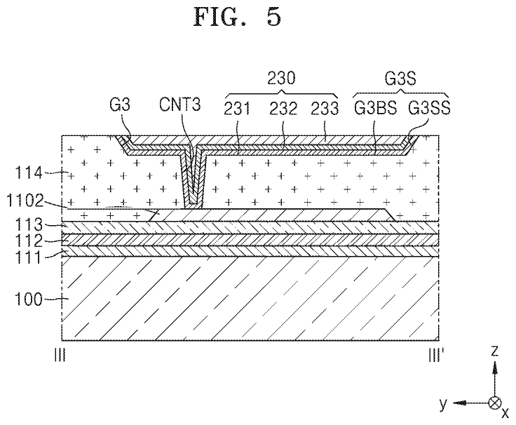

As shown in FIG. 5, which is a schematic cross-sectional view of the display panel 1 of FIG. 4 taken along the line III-III′, the pad 230 may be located over the second portion 1102 of the connection line 1100 to overlap the second portion 1102 of the connection line 1100. In addition, the third insulating layer 114 located under the pad 230 and covering the second portion 1102 of the connection line 1100 may include a contact hole CNT3 provided to electrically connect the pad 230 to the second portion 1102 of the connection line 1100. Therefore, the pad 230 may be electrically connected to the signal line arranged in the display area DA through the connection line 1100. However, the disclosure is not limited thereto. For example, the signal line arranged in the display area DA may be arranged in the same layer (e.g., the third insulating layer 114) as the layer in which the pad 230 is located and may be directly connected to the pad 230. In this case, the display panel 1 may not include the connection line 1100, and the third insulating layer 114 may not include a contact hole CNT3 provided to connect the pad 230 to the connection line 1100.

The pad 230 may have a multi-layer structure including a plurality of sub-layers as shown in FIGS. 3 to 5. For example, the pad 230 may include a main metal layer 232, a protective metal layer 233, and an auxiliary metal layer 231.

The main metal layer 232 may include materials with excellent conductivity. For example, the main metal layer 232 may include Al, copper (Cu), tungsten (W), or molybdenum (Mo). For example, the main metal layer 232 may include Al. The thickness of the main metal layer 232 may be from about 500 Å to about 1,500 Å. For example, the thickness of the main metal layer 232 may be about 1,000 Å.

According to some embodiments, the main metal layer 232 may further include neodymium (Nd) or nickel (Ni). For example, the main metal layer 232 may include an Al—Nd alloy or an Al—Ni alloy. As will be described later, when the main metal layer 232 further includes Nd or Ni, hillock defects may be reduced or prevented during the heat treatment process of the manufacturing process of the display apparatus.

The protective metal layer 233 may be located on the main metal layer 232. The protective metal layer 233 may include materials having low contact resistance and excellent oxidation resistance. For example, the protective metal layer 233 may include Mo, Ti, and Ni. For example, the protective metal layer 233 may include a Mo—Ti—Ni alloy. For example, the protective metal layer 233 may include Ti for reliability, but may further include Mo. Because the contact resistance of a layer including Mo with other metal layers is low, when the protective metal layer 233 includes Mo, the contact resistance between the protective metal layer 233 and the other metal layer may be lowered. However, Mo may have low oxidation resistance. Therefore, Ni with excellent oxidation resistance may be further included. According to some embodiments, the protective metal layer 233 may include Mo: 50 at %, Ti: 30 at %, and Ni: 20 at %. The thickness of the protective metal layer 233 may be from about 2,500 Å to about 3,500 Å. For example, the thickness of the protective metal layer 233 may be about 3,000 Å.

The protective metal layer 233 and the main metal layer 232 may be in surface contact with each other. For example, the main metal layer 232 located under the protective metal layer 233 may have a shape corresponding to the pad groove G3. That is, edges of the main metal layer 232 may be inclined along a surface parallel to an inner side surface G3SS of the pad groove G3. The area of the lower surface of the protective metal layer 233 in a substrate 100 direction (a −z direction) may be less than the area of the upper surface of the protective metal layer 233 in an opposite direction of the substrate 100 (a +z direction). Therefore, the side surface and the lower surface of the protective metal layer 233 may be in surface contact with a surface of the main metal layer 232. In other words, the main metal layer 232 may be in direct contact with the side surfaces and the lower surface of the protective metal layer 233, and may cover the side surfaces and the lower surface of the protective metal layer 233.

Accordingly, as shown in FIG. 4, the main metal layer 232 may surround the protective metal layer 233 in a plan view. Herein, “in a plan view” refers to a view from a direction perpendicular to the substrate 100. For example, when “the main metal layer 232 may surround the protective metal layer 233 in a plan view,” “the main metal layer 232 may surround the protective metal layer 233 when viewed from a direction perpendicular to the substrate 100.” Although the protective metal layer 233 is entirely surrounded by the main metal layer 232 in FIG. 4, the disclosure is not limited thereto. When the signal line arranged in the display area DA is located in the same layer (e.g., the third insulating layer 114) as the layer in which the pad 230 is located and directly connected to the pad 230, the main metal layer 232 may surround a portion of the protective metal layer 233 in a plan view. For example, in a plan view, one side of the protective metal layer 233 directly connected to the signal line arranged in the display area DA is not surrounded by the main metal layer 232. Because the protective metal layer 233 and the main metal layer 232 include different materials from each other, an interface between the protective metal layer 233 and the main metal layer 232 may be viewable in a cross-section of the pad 230.

In general, the display panel, which displays images, etc., may be electrically connected to an electronic chip package or a printed circuit board that provides information about the images. That is, the pads of the display panel may be electrically connected to bumps provided in the electronic chip package, etc. For example, an anisotropic conductive film including conductive particles may be interposed between the pads of the display panel and the bumps of the electronic chip package, etc. and heat and/or pressure may be applied thereto to bond the pads and the bumps to each other in a high temperature and high pressure environment. As a result, the display panel may be electrically connected to the electronic chip package, etc.

In a subsequent heat treatment process following the forming of the pad of the display panel, the upper surface of the pad of the display panel may be oxidized. In this case, when the pad of the display panel is in contact with the bump of the electronic chip package, etc., the contact resistance between the pad of the display panel and the bump of the electronic chip package may be increased. Accordingly, applying a high pressure to the pad of the display panel and the bump of the electronic chip package, etc. is required to bond the pad of the display panel and the bump of the electronic chip package to each other. When a high pressure is applied to the pad of the display panel and the bump of the electronic chip package, a portion of the display panel or the electronic chip package, etc. may be damaged.

However, according to some embodiments, the protective metal layer 233 including materials having a low contact resistance and excellent oxidation resistance may be located on the main metal layer 232. That is, the top of the pad 230 bonded to the bump may be the protective metal layer 233. Accordingly, in the subsequent heat treatment process following the forming of the pad 230, the degree of oxidation of the upper surface of the pad 230 may be reduced. Accordingly, high pressure may not be applied to the pad 230 and the bump of the electronic chip package, etc. to bond the pad 230 and the bump of the electronic chip package, etc. to each other. Thus, the display panel 1, the electronic chip package, etc. may not be damaged. That is, the probability of defects may be lowered in the process of manufacturing the display apparatus.

Moreover, the OLEDoS for displaying an image having an ultra-high resolution may be very small. Accordingly, it may not be easy to apply a high pressure to the pad of the display panel and the bump of the electronic chip package, etc. to bond the pad of the display panel and the bump of the electronic chip package to each other. However, according to some embodiments, the protective metal layer 233 including materials having excellent oxidation resistance may be located on the main metal layer 232. That is, the top of the pad 230 may be the protective metal layer 233. Accordingly, the degree of oxidation of the upper surface of the pad 230 may be reduced. Accordingly, high pressure may not be applied to the pad 230 and the bump of the electronic chip package, etc. to bond the pad 230 and the bump of the electronic chip package, etc. to each other. Thus, the display panel 1, the electronic chip package, etc. may not be damaged. That is, the probability of defects may be lowered in the process of manufacturing the display apparatus.

According to some embodiments, an auxiliary metal layer 231 may be located under the main metal layer 232. That is, the main metal layer 232 may be arranged between the auxiliary metal layer 231 and the protective metal layer 233. The auxiliary metal layer 231 may relatively improve adhesion with a layer (e.g., the third insulating layer 114) including the pad 230 and the pad groove G3. The auxiliary metal layer 231 may include a material that is different from the main metal layer 232.

For example, the auxiliary metal layer 231 may include Ti in consideration of conductivity and adhesion. According to some embodiments, the auxiliary metal layer 231 may further include Mo and Ni. That is, the auxiliary metal layer 231 may include the same material as the protective metal layer 233. In general, a layer for forming the auxiliary metal layer 231, a layer for forming the main metal layer 232, and a layer for forming the protective metal layer 233 may be formed by being continuously deposited in the same chamber of the same deposition cluster. When two layers of the auxiliary metal layer 231, the main metal layer 232, and the protective metal layer 233 consist of the same material, the deposition process may be easier than when the auxiliary metal layer 231, the main metal layer 232, and the protective metal layer 233 all consist of different materials from each other. The thickness of the auxiliary metal layer 231 may be from about 300 Å to about 800 Å. The thickness of the auxiliary metal layer 231 may be about 500 Å.

The auxiliary metal layer 231 and the main metal layer 232 may be in surface contact with each other. Similar to the main metal layer 232, the auxiliary metal layer 231 has a shape corresponding to the pad groove G3, such that the edges of the auxiliary metal layer 231 are inclined along a surface parallel to the inner side surface G3SS of the pad groove G3. Therefore, a surface the auxiliary metal layer 231 may be in surface contact with a surface of the main metal layer 232. In other words, the opposite surface of the surface of the main metal layer 232 in direct contact with the protective metal layer 233 may be in direct contact with the auxiliary metal layer 231. The opposite surface of the surface of the main metal layer 232 in direct contact with the protective metal layer 233 may be covered by the auxiliary metal layer 231. For example, the opposite surface of the surface of the main metal layer 232 in direct contact with the protective metal layer 233 may be in direct contact with the auxiliary metal layer 231. The opposite surface of the surface of the main metal layer 232 in direct contact with the side surface and the lower surface of the protective metal layer 233 may be covered by the auxiliary metal layer 231.

Accordingly, as shown in FIG. 4, the auxiliary metal layer 231 may surround the main metal layer 232 in a plan view. Although, in a plan view, the main metal layer 232 is entirely surrounded by the auxiliary metal layer 231 in FIG. 4, the disclosure is not limited thereto. When the signal line arranged in the display area DA is located in the same layer (e.g., the third insulating layer 114) as the layer in which the pad 230 is located and directly connected to the pad 230, the auxiliary metal layer 231 may surround a portion of the main metal layer 232 in a plan view. For example, in a plan view, one side of the main metal layer 232 directly connected to the signal line arranged in the display area DA is not surrounded by the auxiliary metal layer 231. Because the main metal layer 232 and the auxiliary metal layer 231 include different materials from each other, an interface between the main metal layer 232 and the auxiliary metal layer 231 may be viewable in a cross-section of the pad 230. The other surface of the auxiliary metal layer 231 may be in surface contact with an inner surface G3S of the pad groove G3. Herein, the inner surface of a groove may include the inner surface of the groove and the bottom surface of the groove. For example, the inner surface G3S of the pad groove G3 may include the inner side surface G3SS of the pad groove G3 and a bottom surface G3BS of the pad groove G3. In other words, the opposite surface of the auxiliary metal layer 231 in direct contact with the main metal layer 232 may be in direct contact with the inner surface G3S of the pad groove G3. The auxiliary metal layer 231 may cover the inner surface G3S of the pad groove G3.

The thickness of the main metal layer 232 may be about 10% or more and about 40% or less of the total thickness of the pad 230. If the thickness of the main metal layer 232 exceeds 40% of the total thickness of the pad 230, the upper surface 230S of the pad 230 may be more easily oxidized. As the thickness of the main metal layer 232 is increased, the area of the main metal layer 232, which occupies the upper surface 230S of the pad 230, may be increased. The main metal layer 232 including Al has a lower oxidation resistance than that of the protective metal layer 233 including Mo, Ti, and Ni. Therefore, if the thickness of the main metal layer 232 exceeds 40% of the total thickness of the pad 230, the area of the main metal layer 232, which occupies the upper surface of the pad 230, may be increased and thus, the upper surface 230S of the pad 230 may be more easily oxidized. If the thickness of the main metal layer 232 is less than 10% of the total thickness of the pad 230, the pad 230 may not have sufficient conductivity.

As will be described later, in the process of forming the pad 230, the first connection electrode 210 and the second connection electrode 220 of the thin-film transistor TFT may be formed simultaneously with the pad 230. Therefore, the first connection electrode 210 and the second connection electrode 220 of the thin-film transistor TFT may include a multi-layer structure like the pad 230. Accordingly, sub-layers 211, 212, and 213 of the first connection electrode 210 and sub-layers 221, 222, and 223 of the second connection electrode 220 may include the same material as the auxiliary metal layer 231, the main metal layer 232, and the protective metal layer 233, which are sub-layers of the pad 230. Furthermore, as shown in FIG. 3, the shapes of the sub-layers 211, 212, and 213 and the shapes of the sub-layers 221, 222, and 223 of the second connection electrode 220 in the cross-sectional view may be the same or similar to the shapes of the auxiliary metal layer 231, the main metal layer 232, and the protective metal layer 233, which are the sub-layers of the pad 230.

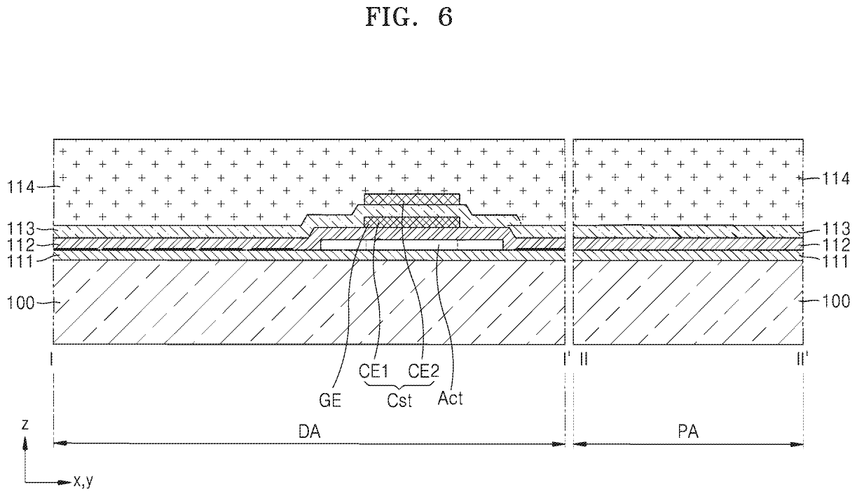

FIGS. 6 to 11 are cross-sectional views schematically illustrating a portion of a process of manufacturing the display panel 1 of FIG. 3. For example, FIGS. 6 to 10 are cross-sectional views schematically illustrating a process of manufacturing the first connection electrode 210, the second connection electrode 220, and the pad 230 of the display panel 1 of FIG. 3.

First, as shown in FIG. 6, the third insulating layer 114 may be formed on the substrate 100. The semiconductor layer Act, the gate electrode GE, and the storage capacitor Cst included in the thin-film transistor TFT may be located on the display area DA of the substrate 100. For example, before forming the third insulating layer 114 on the substrate 100, the buffer layer 111 may be formed on the substrate 100, the semiconductor layer Act may be formed on the buffer layer 111, the first insulating layer 112 may be formed on the semiconductor layer Act, and the gate electrode GE may be formed on the first insulating layer 112. The gate electrode GE may be a first capacitor electrode CE1 of the storage capacitor Cst. Subsequently, the second insulating layer 113 may be formed on the gate electrode GE, and the second capacitor electrode CE2 may be formed on the second insulating layer 113. Subsequently, the third insulating layer 114 may be formed on the second capacitor electrode CE2. That is, the third insulating layer 114 may be formed above the substrate 100.

In other words, before forming the third insulating layer 114 above the substrate 100, a portion of the pixel circuit PC described above with reference to FIG. 3 is formed on the substrate 100. That is, the semiconductor layer ACT and the gate electrode GE included in the thin-film transistor TFT may be formed on the substrate 100, and the first capacitor electrode CE1 and the second capacitor electrode CE2 included in the storage capacitor Cst may be formed on the substrate 100. The buffer layer 111 may be formed on the substrate 100, the first insulating layer 112 may be formed between the semiconductor layer Act and the gate electrode GE, and the second insulating layer 113 may be formed between the gate electrode GE and the second capacitor electrode CE2.

The third insulating layer 114 may be formed on the second capacitor electrode CE2. For example, the third insulating layer 114 may be formed on the second capacitor electrode CE2 and on the entire surface of the substrate 100. Accordingly, as shown in FIG. 6, a portion of the third insulating layer 114 may be located on the display area DA of the substrate 100, and the other portion of the third insulating layer 114 may be located on the peripheral area PA of the substrate 100. As described above, the third insulating layer 114 may include inorganic materials such as SiO_{X}, SiN_{X}, and/or SiO_{X}N_{Y}, and may include a single layer or multiple layers. The third insulating layer 14 including inorganic materials may be formed by chemical vapor deposition (CVD) or atomic layer deposition (ALD).

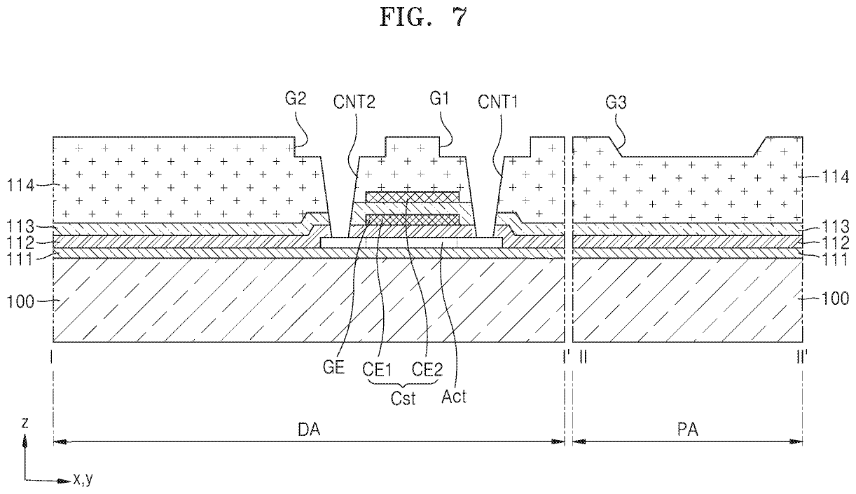

Subsequently, as shown in FIG. 7, the pad groove G3 may be formed in the third insulating layer 114. In the process of forming the pad groove G3, the first groove G1 and the second groove G2 may be formed simultaneously with the pad groove G3. At the same time, contact holes that overlap the grooves may also be formed. The contact holes overlap the grooves and are connected to the overlapping grooves, thereby exposing layers located under the third insulating layer 114. In other words, a portion of the third insulating layer 114 may be partially removed from the upper surface of the third insulating layer 114 in the thickness direction, and the other portion of the third insulating layer 114 may be entirely from the upper surface of the third insulating layer 114 in the thickness direction. In addition, a portion of the second insulating layer 113 may be entirely removed from the upper surface of the second insulating layer 113 in the thickness direction, and a portion of the first insulating layer 112 may be entirely removed from the upper surface of the first insulating layer 112 in the thickness direction.

That is, a portion of the third insulating layer 114, which is partially removed from the upper surface of the third insulating layer 114 in the thickness direction, corresponds to the groove. The other portion of the third insulating layer 114 of which is entirely removed from the upper surface of the third insulating layer 114 in the thickness direction, the portion of the second insulating layer 113 of which is entirely removed from the upper surface of the second insulating layer 113 in the thickness direction, and the portion of the first insulating layer 112 of which is entirely removed from the upper surface of the first insulating layer 112 in the thickness direction correspond to the portion where the grooves overlap the contact holes.

A photolithography process using a half-tone mask and an etching process may be used to form the contact holes and the grooves. Here, a negative photoresist or a positive photoresist may be used in the photolithography process, but for convenience of explanation, the photolithography process in which the negative photoresist is used is described. The half-tone mask may be divided into a transmission area configured to transmit light, a semi-transmission area configured to partially transmit light, and a blocking area configured to block the transmission of light, according to light transmittance of the half-tone mask.

After applying a negative photoresist on an insulating layer, the photoresist is exposed to light and developed through the half-tone mask, and thus, a first portion corresponding to the transmission area of the half-tone mask among the photoresists may not be removed to remain thick, and a second portion corresponding to the semi-transmission area of the half-tone mask may be partially removed to remain thin. On the other hand, a third portion corresponding to the blocking area of the half-tone mask among the photoresists is not exposed to light to be completely removed.

A photoresist pattern thus formed is used as an etching mask to etch the insulating layer. Then, the insulating layer is etched after the photoresist pattern is removed by at least the thickness of the second portion by using an ashing process. Accordingly, a portion of the groove corresponding to the third portion of the photoresist and a contact hole overlapping the portion are formed, and the other portion of the groove may be formed in an area corresponding to the second portion of the photoresist. However, the disclosure is not limited thereto, and any process that is commonly used to form grooves and contact holes in the insulating layer may be used.

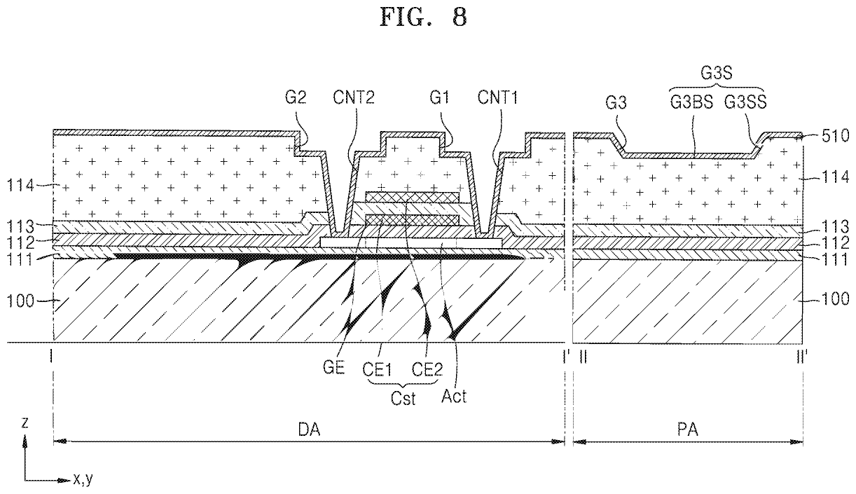

As shown in FIG. 8, an auxiliary metal layer forming layer 510 may be formed on the third insulating layer 114. For example, the auxiliary metal layer forming layer 510 may be formed on the third insulating layer 114 to correspond to the front surface of the substrate 100. For example, by using a sputtering method, etc. in the chamber of the deposition cluster, the auxiliary metal layer forming layer 510 may be formed on the front surface of the substrate 100. Accordingly, the auxiliary metal layer forming layer 510 may cover the inner surface G3S of the pad groove G3 of the third insulating layer 114. The auxiliary metal layer forming layer 510 may cover the inner surface of the first groove G1 and the second groove G2, and may also cover the inner surfaces of the contact holes. The auxiliary metal layer forming layer 510 may include Ti. According to some embodiments, the auxiliary metal layer forming layer 510 may further include Mo and Ni. For example, the auxiliary metal layer forming layer 510 may include a Mo—Ti—Ni alloy.

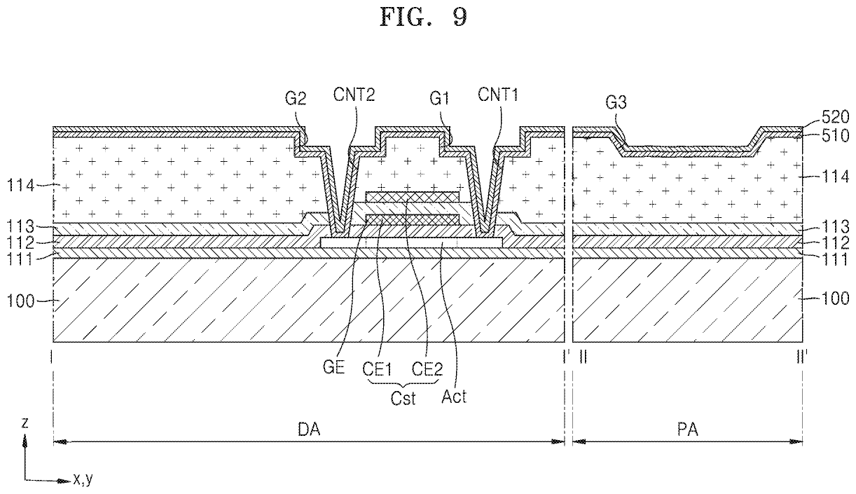

As shown in FIG. 9, a main metal layer forming layer 520 may be formed on the auxiliary metal layer forming layer 510. For example, the main metal layer forming layer 520 may be formed on the auxiliary metal layer forming layer 510 to correspond to the front surface of the substrate 100. For example, by using a sputtering method, etc. in the chamber of the deposition cluster, the main metal layer forming layer 520 may be formed on the front surface of the substrate 100. Accordingly, the main metal layer forming layer 520 may cover the auxiliary metal layer forming layer 510 in the pad groove G3. The main metal layer forming layer 520 may cover the auxiliary metal layer forming layer 510 in the first groove G1 and the second groove G2, and may also cover the auxiliary metal layer forming layer 510 in the contact holes.

The main metal layer forming layer 520 may include Al, Cu, W, or Mo. For example, the main metal layer forming layer 520 may include Al. According to some embodiments, the main metal layer forming layer 520 may further include Nd or Ni. For example, the main metal layer forming layer 520 may include an Al—Nd alloy or an Al—Ni alloy.

Subsequent processes after the manufacturing process of the first connection electrode 210, the second connection electrode 220, and the pad 230 of the display apparatus may include a heat treatment process. When the pad 230 is formed using the main metal layer forming layer 520 consisting of pure Al, a hillock defect may occur in the subsequent heat treatment process. However, according to some embodiments, the main metal layer forming layer 520 may further include Nd or Ni. Therefore, hillock defect in the subsequent heat treatment process may be prevented or reduced.

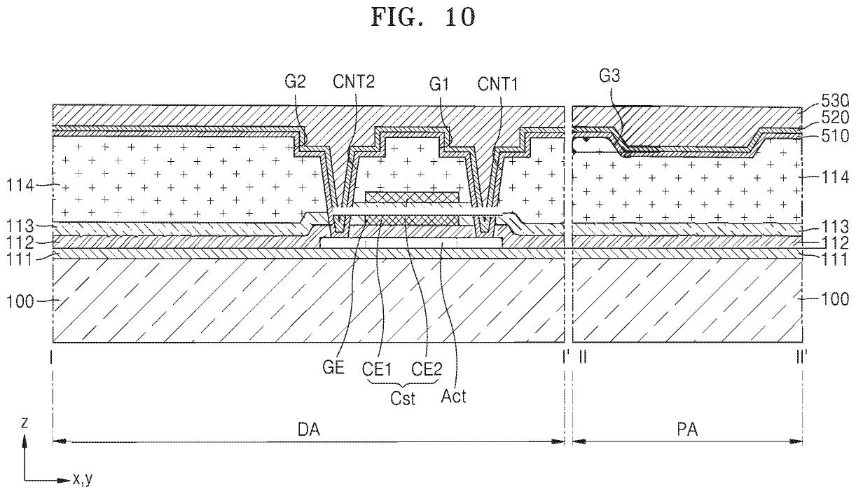

As shown in FIG. 10, a protective metal layer forming layer 530 may be formed on the main metal layer forming layer 520. For example, the protective metal layer forming layer 530 may be formed on the main metal layer forming layer 520 to correspond to the front surface of the substrate 100. For example, by using a sputtering method, etc. in the chamber of the deposition cluster, the protective metal layer forming layer 530 may be formed on the front surface of the substrate 100. Accordingly, the protective metal layer forming layer 530 may cover the main metal layer forming layer 520 in the pad groove G3. The protective metal layer forming layer 530 may cover the main metal layer forming layer 520 in the first groove G1 and the second groove G2, and may also cover the main metal layer forming layer 520 in the contact holes.

The protective metal layer forming layer 530 may include Mo, Ti, and Ni. For example, the protective metal layer forming layer 530 may include a Mo—Ti—Ni alloy. That is, the protective metal layer forming layer 530 may consist of the same material as the auxiliary metal layer forming layer 510. In general, the auxiliary metal layer forming layer 510, the main metal layer forming layer 520, and the protective metal layer forming layer 530 may be continuously deposited in the same chamber of the same deposition cluster. When two layers of the auxiliary metal layer forming layer 510, the main metal layer forming layer 520, and the protective metal layer forming layer 530 include the same material, the deposition process may be easier than when all of the auxiliary metal layer forming layer 510, the main metal layer forming layer 520, and the protective metal layer forming layer 530 include different materials from each other.

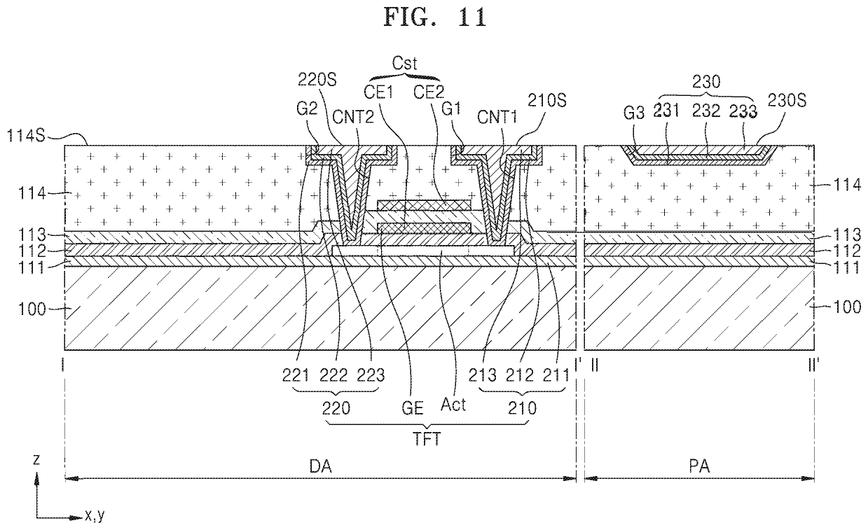

As shown in FIG. 11, a portion of the auxiliary metal layer forming layer 510, a portion of the main metal layer forming layer 520, and a portion of the protective metal layer forming layer 530, which are located on the third insulating layer 114 outside the pad groove G3, may each be removed. A portion of the auxiliary metal layer forming layer 510, a portion of the main metal layer forming layer 520, and a portion of the protective metal layer forming layer 530, which are located on the third insulating layer 114 outside the first groove G1 and the second groove G2, may each be removed. In this case, a portion of the auxiliary metal layer forming layer 510, a portion of the main metal layer forming layer 520, and a portion of the protective metal layer forming layer 530, which are arranged in the pad groove G3, may not be removed. A portion of the auxiliary metal layer forming layer 510, a portion of the main metal layer forming layer 520, and a portion of the protective metal layer forming layer 530, which are arranged in the first groove G1 and the second groove G2, may not be removed. A portion of the auxiliary metal layer forming layer 510, a portion of the main metal layer forming layer 520, and a portion of the protective metal layer forming layer 530, which are arranged in the contact holes, may not be removed. Accordingly, the first connection electrode 210, the second connection electrode 220, and the pad 230 described with reference to FIG. 3 may be formed.

According to some embodiments, each of the portion of the auxiliary metal layer forming layer 510, the portion of the main metal layer forming layer 520, and the portion of the protective metal layer forming layer 530 may be removed by a polishing process, such as chemical mechanical polishing (CMP). Accordingly, the upper surface 114S of the third insulating layer 114 may form a flat surface with the upper surface 230S of the pad 230 arranged in the pad groove G3. That is, the upper surface 114S of the third insulating layer 114 and the upper surface 230S of the pad 230 may form a flat surface without forming a step difference therebetween. The upper surface 114S of the third insulating layer 114 may form a flat surface with the upper surface 210S of the first connection electrode 210 in the first groove G1 and the upper surface 220S of the second connection electrode 220 in the second groove G2. That is, the upper surface 114S of the third insulating layer 114 may form a flat surface with the upper surface 210S of the first connection electrode 210 and the upper surface 220S of the second connection electrode 220 without forming a step difference with the upper surface 210S of the first connection electrode 210 and the upper surface 220S of the second connection electrode 220.

According to some embodiments as described above, a display apparatus in which the probability of defects may be reduced in the manufacturing process may be implemented. However, the scope of the disclosure is not limited to these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims, and their equivalents.

What is claimed is:

1. A display apparatus comprising:
a substrate comprising a display area and a peripheral area outside the display area;
a display element on the display area; and
a pad on the peripheral area and comprising a main metal layer and a protective metal layer on the main metal layer and comprising molybdenum (Mo), titanium (Ti), and nickel (Ni).

2. The display apparatus of claim 1, wherein the protective metal layer is in surface contact with the main metal layer.

3. The display apparatus of claim 1, wherein the main metal layer surrounds the protective metal layer in a plan view.

4. The display apparatus of claim 1, wherein the pad further comprises an auxiliary metal layer under the main metal layer.

5. The display apparatus of claim 4, wherein the auxiliary metal layer comprises Ti.

6. The display apparatus of claim 5, wherein the auxiliary metal layer further comprises Mo and Ni.

7. The display apparatus of claim 4, wherein the main metal layer is in surface contact with the auxiliary metal layer.

8. The display apparatus of claim 7, wherein the auxiliary metal layer surrounds the main metal layer in a plan view.

9. The display apparatus of claim 1, wherein the main metal layer comprises aluminum (Al).

10. The display apparatus of claim 9, wherein the main metal layer further comprises neodymium (Nd) or Ni.

11. The display apparatus of claim 1, wherein the substrate is a semiconductor substrate.

12. The display apparatus of claim 1, further comprising an insulating layer above the substrate and comprising a pad groove, wherein
the pad is in the pad groove of the insulating layer.

13. The display apparatus of claim 12, wherein an upper surface of the insulating layer and an upper surface of the pad form a flat surface.

14. A method of manufacturing a display apparatus, the method comprising:
forming an insulating layer on a substrate comprising a display area and a peripheral area surrounding the display area;
forming a pad groove in a portion of the insulating layer on the peripheral area;
forming an auxiliary metal layer forming layer on the insulating layer to cover the inner surface of the pad groove;
forming a main metal layer forming layer on the auxiliary metal layer forming layer to cover the auxiliary metal layer forming layer in the pad groove;
forming a protective metal layer forming layer comprising molybdenum (Mo), titanium (Ti), and nickel (Ni) on the main metal layer forming layer to cover the main metal layer forming layer in the pad groove; and
forming a pad by removing each of a portion of the auxiliary metal layer forming layer, a portion of the main metal layer forming layer, and a portion of the protective metal layer forming layer, which are on the insulating layer outside the pad groove.

15. The method of claim 14, wherein the forming of the pad by removing each of the portion of the auxiliary metal layer forming layer, the portion of the main metal layer forming layer, and the portion of the protective metal layer forming layer comprises:
proceeding chemical mechanical polishing (CMP) to expose the upper surface of the insulating layer and for the upper surface of the insulating layer to form a flat surface with the upper surface of the pad.

16. The method of claim 14, wherein the auxiliary metal layer forming layer comprises Ti.

17. The method of claim 16, wherein the auxiliary metal layer forming layer further comprises Mo and Ni.

18. The method of claim 14, wherein the main metal layer forming layer comprises aluminum (Al).

19. The method of claim 18, wherein the main metal layer forming layer further comprises neodymium (Nd) or Ni.

20. The method of claim 14, wherein the substrate is a semiconductor substrate.
